(19) United States
(12) Patent Application Publication
(10) Pub. No.: US 2025/0271773 A1
(43) Pub. Date: Aug. 28, 2025

(54) EXPOSURE APPARATUS, CONTROL METHOD THEREFOR, INFORMATION PROCESSING APPARATUS, INFORMATION PROCESSING METHOD, NON-TRANSITORY COMPUTER READABLE MEDIUM, AND ARTICLE MANUFACTURING METHOD

(71) Applicant: CANON KABUSHIKI KAISHA, Tokyo (JP)

(72) Inventors: MITSUHIDE NISHIMURA, Tochigi (JP); SHINGO HANYUDA, Tochigi (JP)

(21) Appl. No.: 19/063,911

(22) Filed: Feb. 26, 2025

(30) Foreign Application Priority Data
Feb. 27, 2024 (JP) 2024-027869

(51) Int. Cl. G03F 7/00

(52) U.S. Cl. CPC G03F 7/70525; G03F 7/70325; G03F 7/7085

(57) ABSTRACT

An exposure apparatus for exposing an exposure region of a substrate by projecting a pattern of an original to the exposure region by a projection optical system, includes a measurement system configured to measure a height of the substrate at each of a plurality of measurement points in the exposure region, a user interface configured to prompt a user to make a setting concerning use of each of the plurality of measurement points, and a controller configured to control a focus operation of the exposure region with respect to an image plane of the projection optical system by using a measurement result of the measurement system based on the setting.

### BACKGROUND OF THE INVENTION

### Field of the Invention

The present invention relates to an exposure apparatus, a control method therefor, an information processing apparatus, an information processing method, a non-transitory computer readable medium, and an article manufacturing method.

### Description of the Related Art

As an exposure apparatus used in the manufacture of an article such as a semiconductor device, there are a step-and-repeat type exposure apparatus (stepper) and a step-and-scan type exposure apparatus (scanner). The stepper is a low cost apparatus as compared to the scanner, and is used in a step in which high resolution and high precision overlay are not required. In the stepper, after a substrate is step-driven so that a shot region on the substrate is positioned in an exposure region under a projection optical system, a height measurement apparatus measures the height, a focus operation is performed based on a measurement result, and then the shot region is exposed.

Japanese Patent Laid-Open No. 11-102852 discloses an exposure method of detecting the height of an exposure region on a substrate, calculating the average value of the highest height of the region and the lowest height of the region, and performing scan exposure while matching the image formation position of a projection optical system with the average height on the substrate.

In an exposure apparatus that measures the height of the substrate at each of a plurality of measurement points in an exposure region on the substrate and performs a focus operation based on the measurement results, it may be undesirable to perform the focus operation using the measurement results at all the measurement points. For example, if a focus operation is performed in consideration of a measurement result at a measurement point arranged in a region that has low repeatability among a plurality of exposure regions and is not important for the focus operation, an important region may be exposed in a defocus state.

### SUMMARY OF THE INVENTION

The present invention provides a technique advantageous in adjusting a focus operation in an exposure apparatus including a measurement system capable of measuring the height of a substrate at each of a plurality of measurement points in an exposure region.

One of aspects of the present invention provides an exposure apparatus for exposing an exposure region of a substrate by projecting a pattern of an original to the exposure region by a projection optical system, comprising: a measurement system configured to measure a height of the substrate at each of a plurality of measurement points in the exposure region; a user interface configured to prompt a user to make a setting concerning use of each of the plurality of measurement points; and a controller configured to control a focus operation of the exposure region with respect to an image plane of the projection optical system by using a measurement result of the measurement system based on the setting.

Further features of the present invention will become apparent from the following description of exemplary embodiments with reference to the attached drawings.

### BRIEF DESCRIPTION OF THE DRAWINGS

FIG. 1 is a view exemplifying the configuration of an exposure apparatus according to an embodiment;

FIG. 2 is a view exemplifying the configuration of a measurement system;

FIG. 3 is a view for explaining an example of the operation principle of the measurement system;

FIG. 4 is a view exemplifying the arrangement of a plurality of measurement points in a measurement region of the measurement system;

FIG. 5 is a view exemplifying a user interface screen provided to a user by a display device forming a user interface of a controller;

FIG. 6 is a flowchart exemplifying the operation of the exposure apparatus or a control apparatus associating with setting of the plurality of measurement points and a focus operation; and

FIG. 7 is a block diagram exemplifying the configuration of the controller, the control apparatus, or an information processing apparatus that controls the exposure apparatus.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

In the specification and the accompanying drawings, directions will be indicated on an XYZ coordinate system in which directions parallel to the surface of a substrate are defined as the X-Y plane. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are OX, OY, and OZ, respectively.

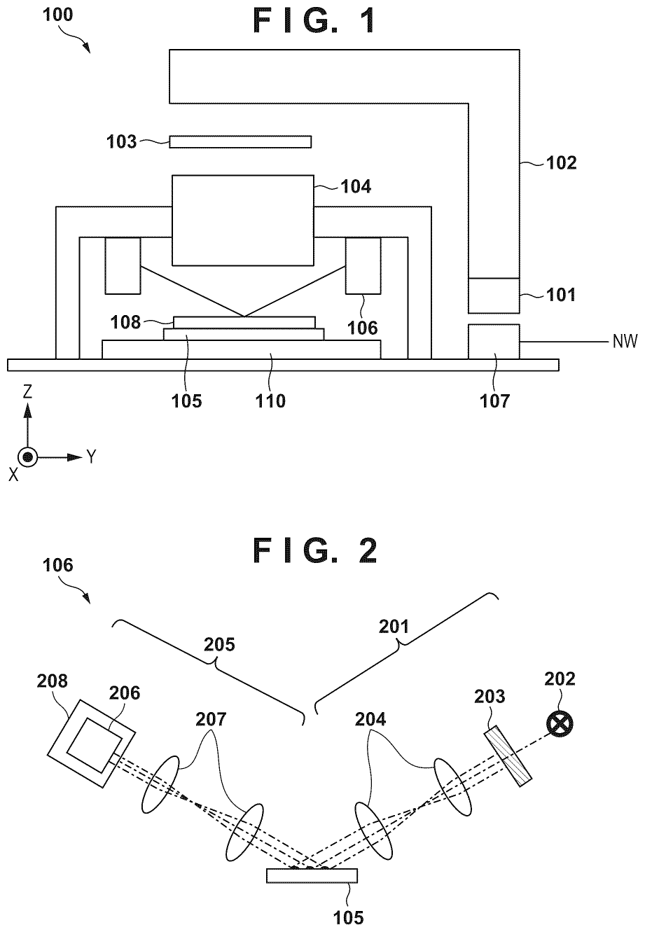

FIG. 1 is a view showing the configuration of an exposure apparatus 100 according to an embodiment. The exposure apparatus 100 is one form of a lithography apparatus used in a photolithography step for manufacturing an article such as a semiconductor device or a display device. The exposure apparatus 100 exposes a substrate 108 by projecting the pattern of an original to the substrate 108 by a projection optical system 104. The exposure apparatus 100 can expose the substrate 108 by a step-and-repeat method or a step-and-scan method. The present invention is not limited to the exposure method, but an example in which the exposure apparatus 100 is a step-and-repeat type exposure apparatus will be described below.

The exposure apparatus 100 exposes an exposure region (to be also referred to as a shot region hereinafter) of the substrate 108 by projecting the pattern of an original 103 to the exposure region by the projection optical system 104. The substrate 108 has a photosensitive material such as a photoresist on its surface, and exposure of the substrate 108 indicates exposure of the photosensitive material. An illumination optical system 102 illuminates the original 103 by guiding light from a light source 101. The light source 101 can be formed by, for example, an i-line mercury lamp, an excimer laser, or the like. A pattern to be projected is drawn on the original 103. The light having passed through the original 103 reaches the substrate 108 on a stage 105 through the projection optical system 104 to form the image of the pattern of the original 103. The stage 105 includes a substrate chuck that holds the substrate 108. A substrate driving mechanism 110 can drive or position the stage 105 so that the substrate 108 is driven or positioned with respect to six axes including the X-axis, the Y-axis, the Z-axis, θX-axis, the θY-axis, and the θZ-axis. The image of the pattern of the original 103 projected on the substrate 108 is transferred to the photosensitive material such as a resist applied in advance to the surface of the substrate 108. By repeating an operation of step-driving the stage 105 that holds the substrate 108 and an operation of exposing the exposure region (shot region), the image of the pattern of the original 103 is transferred as a latent image to the photosensitive material in the plurality of exposure regions on the substrate 108. A position measurement apparatus such as an interferometer or an encoder (not shown) measures the position and posture of the stage 105 with high accuracy, and driving or positioning of the stage 105 (substrate 108) by the substrate driving mechanism 110 can be controlled in accordance with a measurement result. This can implement overlay exposure with high accuracy. The pattern transferred as a latent image to the photosensitive material in the exposure step is converted into a physical pattern in a development step.

In the exposure step, a measurement system 106 measures the height of the substrate 108 in the exposure region to adjust the height and tilt of the substrate 108 with respect to the image of the pattern of the original 103 (that is, the image plane of the projection optical system 104). Then, based on a measurement result, at least one of the height and the tilt of the stage 105 can be controlled. Controlling at least one of the height and the tilt of the stage 105 to match the reference surface (for example, the surface or a surface offset from the surface) of the photosensitive material in the exposure region on the substrate 108 with the image plane of the projection optical system 104 will be referred to as a focus operation hereinafter.

The measurement system 106 can be configured to measure a height distribution that can be represented by the heights of the substrate 108 at a plurality of measurement points in the exposure region (shot region) on the substrate 108. The size of the measurement region as the visual field of the measurement system 106 can be determined in accordance with required specifications. In an example, the measurement region of the measurement system 106 can be determined to cover the entire maximum exposure region in the exposure apparatus 100. Alternatively, the measurement region may be a region smaller than the maximum exposure region in the exposure apparatus 100. An example in which the measurement region of the measurement system 106 covers the entire exposure region (shot region) of the substrate 108, that is, an example in which the height distribution of the exposure region can be obtained by performing measurement once by the measurement system 106 will be described below. However, the height distribution of the exposure region may be obtained by performing measurement a plurality of times by the measurement system 106.

The configuration of the measurement system 106 will be described with reference to FIG. 2. The measurement system 106 detects the height at each of a plurality of measurement points in the measurement region. The measurement system 106 can include a light projector 201 and a light receiver 205. The light projector 201 can include a light source 202 that makes light obliquely enter the surface of the substrate 108 as an object on the stage 105, a two-dimensionally arrayed light projection pattern 203, and a light projecting optical system 204 used to project the light projection pattern 203 to the object. Note that the light projecting optical system 204 can be omitted depending on the kind of the light source 202 and/or the distance between the light projection pattern 203 and the object. Alternatively, the light projection pattern 203 and the object may be set in the relationship of a Scheimpflug optical system by using the light projecting optical system 204. By adopting the Scheimpflug optical system, the entire surface of the light projection pattern 203 can by focused on the object, thereby improving the measurement accuracy. Furthermore, when measuring the height of the object, the Scheimpflug optical system can prevent the measurement value from changing due to a local tilt of the object.

The light receiver 205 can include a light receiving optical system 207 and a camera 208. The light reflected by the object enters the camera 208 via the light receiving optical system 207. The camera 208 can include an image sensor 206 that includes a plurality of two-dimensionally arrayed pixels. Note that the light receiving optical system 207 can be omitted depending on the kind of the light source 202 and the distance between the object and the camera 208. Alternatively, the object and the image sensor 206 may be set in the relationship of a Scheimpflug optical system by using the light receiving optical system 207. By adopting the Scheimpflug optical system, the entire surface of object can be focused on the image plane of the image sensor 206. Furthermore, when measuring the height of the object, the Scheimpflug optical system can prevent the measurement value from changing due to the tilt of the object.

The exposure apparatus 100 includes a controller 107. The controller 107 can be formed as, for example, a control apparatus that controls the operation of the exposure apparatus 100 by controlling the light source 101, the illumination optical system 102, the projection optical system 104, the measurement system 106, the substrate driving mechanism 110, and the like. The controller 107 can be formed by a general-purpose or dedicated computer incorporating a program.

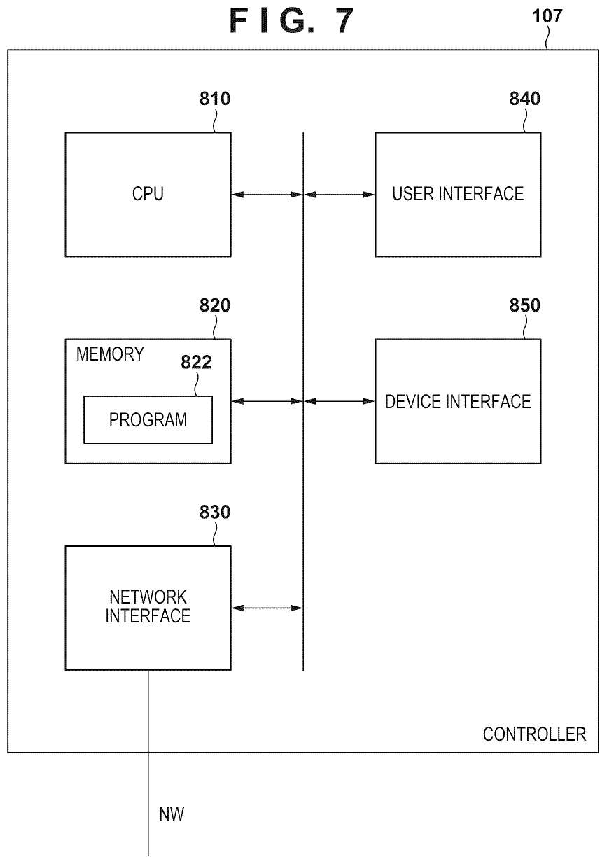

FIG. 7 shows an example of the configuration of the controller 107. The controller 107 can include, for example, a CPU (processor) 810, a memory 820, a network interface 830, a user interface 840, and a device interface 850. A program 822 to be executed by the CPU 810 can be held in or loaded into the memory 820. The program 822 can be stored in a computer-readable memory medium and used for a transaction. For example, the program 822 stored in a computer-readable memory medium (not shown) can be read out from the memory medium by the device interface 850 and loaded into the memory 820. Alternatively, the program 822 may be loaded from an external device holding it into the memory 820 via a network NW. The program 822 loaded into the memory 820 may be held non-transitory in the memory 820. The user interface 840 includes, for example, a keyboard, a pointing device such as a mouse, and a display device (including a touch panel display), and can provide information to the user and acquire information from the user. The device interface 850 has a function of performing connection to various kinds of devices or components such as the light source 101, the illumination optical system 102, the projection optical system 104, the measurement system 106, and the substrate driving mechanism 110.

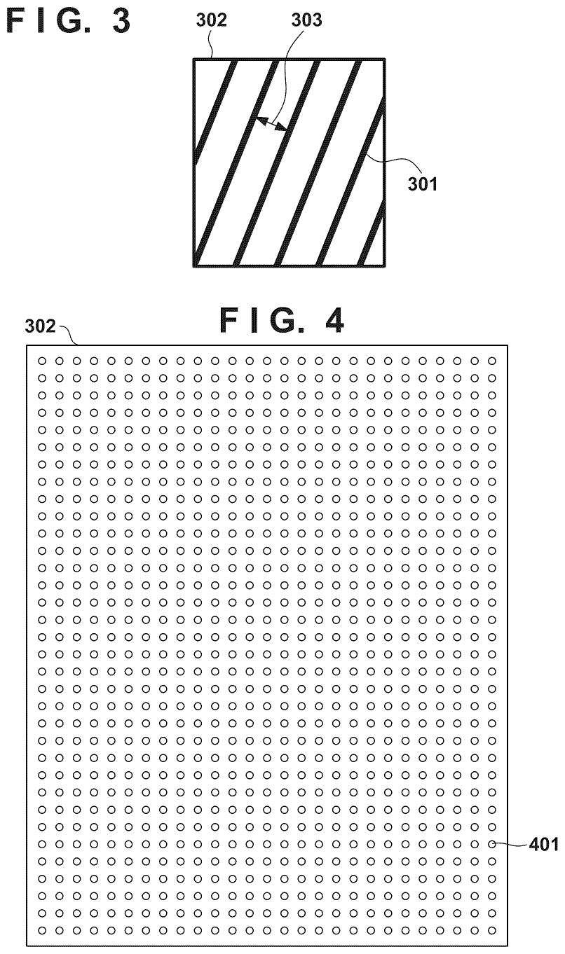

FIG. 3 exemplarily shows a light projection pattern image (the image of the light projection pattern image 203) 301 formed by projecting the light projection pattern to the substrate 108 by the light projector 201 of the measurement system 106. The light projection pattern image 301 can be formed in a measurement region 302 of the measurement system 106. The light projection pattern image 301 can include a plurality of bars, as schematically shown in FIG. 3. To precisely measure a height map (height distribution) in the measurement region 302 (or the exposure region), it is necessary to reduce the interval between the bars in the light projection pattern image 301. If the image sensor 206 is a two-dimensional image sensor, a height map in the measurement region 302 of the surface of the substrate 108 can be obtained at a measurement interval defined by the light projection pattern image 301 projected to the substrate 108 and the pixel density of the image sensor 206.

The light projection pattern image 301 has information corresponding to the height distribution of the surface of the substrate 108 in the measurement region 302 (exposure region). The controller 107 can obtain the height map (height distribution) in the measurement region 302 (exposure region) based on the light projection pattern image 301 captured by the image sensor 206. Note that the controller 107 may execute at least part of processing of forming the height map (height distribution) based on the output from the image sensor 206. In this case as well, the measurement system 106 can be considered to measure the height in the measurement region 302 (exposure region). The measurement system 106 can measure the height of the surface of the substrate 108 at each of a plurality of measurement points in the measurement region 302 (exposure region). The controller 107 can control the focus operation of the exposure region with respect to the image plane of the projection optical system 104 based on the output from the measurement system 106.

FIG. 4 shows an example of the arrangement of a plurality of measurement points 401 in the measurement region 302. The light projection pattern image 301 exemplified in FIG. 3 may be formed (projected) at each measurement point 401 or formed (projected) over the measurement region 302. The plurality of measurement points 401 are uniformly arranged in the measurement region 302 in the example shown in FIG. 4, but the plurality of measurement points 401 need not uniformly be arranged. The controller 107 can obtain a height map in the exposure region on the surface using the measurement system 106 before setting of the focus operation to be described below, and the height map can be provided to the user by the display device forming the user interface 840.

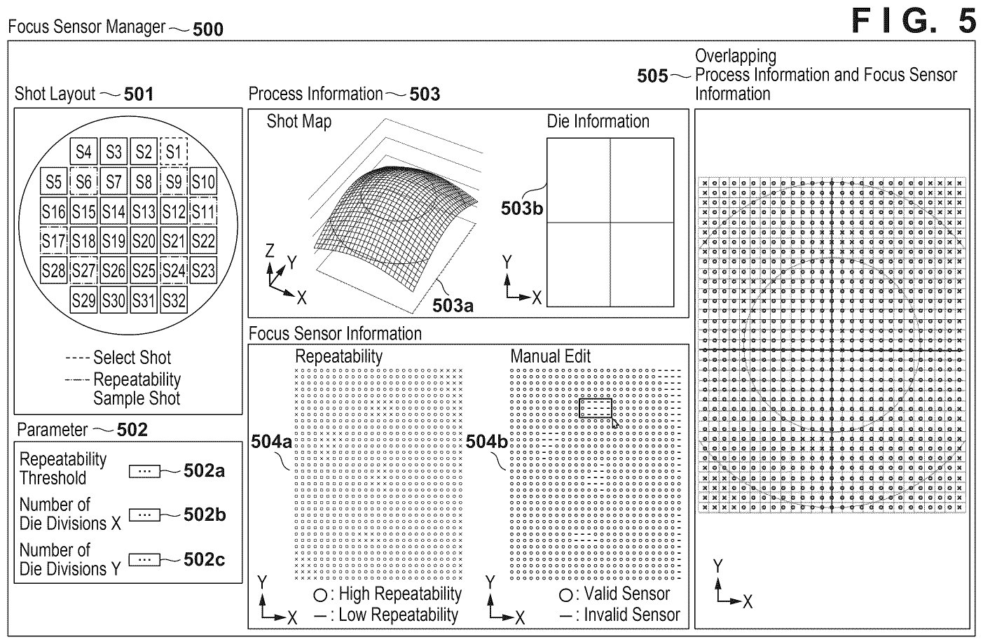

FIG. 5 exemplarily shows a user interface screen 500 provided to the user by the display device forming the user interface 840 of the controller 107. The display format, the display position, and the like of each piece of information that can be provided to the user by the user interface screen 500 can be changed appropriately.

A display region 501 is a region where a shot layout representing the arrangement of a plurality of shot regions (exposure regions) defined on the substrate 108 is displayed. A shot region indicated by dotted lines represents a shot region for editing, and in the example shown in FIG. 5, a shot region S1 is selected for editing. Shot regions indicated by alternate long and short dashed lines represent a plurality of sample shot regions for evaluating the repeatability of a height measurement result. The plurality of sample shot regions can arbitrarily be set by the user. The step-and-repeat type exposure apparatus sequentially executes exposure processing for a plurality of shot regions S1 to S32 by stepping. An example in which the measurement region 302 is the same as the exposure region (shot region) or covers the entire exposure region (shot region) will be described.

A display region 502 is a region where parameters are displayed. More specifically, the display region 502 is a region for displaying parameters associated with pieces of information to be displayed in a plurality of display regions 503, 504, and 505 included in the user interface screen 500. A parameter 502a represents a threshold for evaluating the repeatability of a height measurement result. In this example, if a numerical value indicating the repeatability of a height measurement result among the plurality of sample shot regions (selected exposure regions) is smaller than the threshold set as the parameter 502a, it is determined that the repeatability is high, and if the numerical value exceeds the threshold, it is determined that the repeatability is low. The repeatability is evaluated for the measurement result at each of the plurality of measurement points. The repeatability is an index (index value) representing variations among the plurality of sample shot regions (selected exposure regions), and can be, for example, a standard deviation (o).

Parameters 502b and 502c are parameters for setting the number of dies forming the shot region (exposure region). The parameter 502b provides the user with a function of setting the number of dies in the X direction (the division number in the X direction), and the parameter 502c provides the user with a function of setting the number of dies in the Y direction (the division number in the Y direction).

The display region 503 is a region where process information is displayed. The process information can include a height map 503a of the shot region (exposure region) of the substrate and die information 503b. In the example shown in FIG. 5, the height map 503a is the height map of the shot region S1 selected in the display region 501, and the die information 503b indicates the arrangement of the plurality of dies in each shot region in the shot layout shown in the display region 501. Note that the display example shown in FIG. 5 is merely an example and, for example, the height map 503a may display the height by color, may be changeable in scale, or may display the difference of the height map of another shot region. The die information 503b is displayed in accordance with the pieces of input information to the parameters 502b and 502c of the display region 502. The parameter 502b is a parameter for setting the number of dies in the X direction (the division number in the X direction), and the parameter 502c is a parameter for setting the number of dies in the Y direction (the division number in the Y direction).

The display region 504 is a region where information concerning the measurement system 106 (focus sensor) is displayed. The display region 504 can include a repeatability map 504a obtained by mapping repeatability information representing the repeatability of the height measurement result to each of the plurality of measurement points 401, and a setting map 504b obtained by mapping a setting state associated with the use of each of the plurality of measurement points 401 of the measurement system 106 to each of the plurality of measurement points 401.

The repeatability map 504a indicates a result of evaluating the repeatability of each of the height measurement results obtained by measuring in advance, by the measurement system 106, the sample shot regions S6, S9, S11, S17, S24, and S27 set in the display region 501. The sample shot regions can be changed by the user. In this evaluation, if a numerical value representing the repeatability of the height measurement result among the plurality of sample shot regions is smaller than the threshold set as the parameter 502a, it is determined that the repeatability is high, and if the numerical value exceeds the threshold, it is determined that the repeatability is low. In the display region 504, the measurement point 401 at which the numerical value representing the repeatability is smaller than the threshold and the measurement point 401 at which the numerical value representing the repeatability exceeds the threshold can be distinguished and displayed. In the example shown in FIG. 5, the measurement point (Low Repeatability) at which the numerical value representing the repeatability is smaller than the threshold is indicated by “x” and the measurement point (High Repeatability) at which the numerical value representing the repeatability exceeds the threshold is indicated by “O”. Note that a method of evaluating the repeatability and a method of presenting the evaluation result are not limited to the above example. The repeatability map 504a as information displayed in the display region 504 may be understood to include information representing the arrangement of the plurality of measurement points 401 arranged in the measurement region or the exposure region.

The setting map 504b provides a user interface for prompting the user to make a setting concerning the use of each of the plurality of measurement points 401 in the focus operation. In an example, the setting map 504b provides a user interface for prompting the user to set whether to use each of the plurality of measurement points 401 in the focus operation. In the example shown in FIG. 5, the measurement point 401 (Valid Sensor) used for the focus operation is indicated by “O”, and the measurement point 401 (Invalid Sensor) not used for the focus operation is indicated by “-”. Distinguishment between the measurement point used for the focus operation and that not used for the focus operation is not limited to this, and for example, these measurement points may be distinguished by colors or the like. The setting map 504b as information displayed in the display region 504 may be understood to include information representing the arrangement of the plurality of measurement points 401 arranged in the measurement region or the exposure region.

The measurement point 401 (Valid Sensor) used for the focus operation is the measurement point 401 used by the controller 107 to control the focus operation, and the controller 107 controls the focus operation based on the measurement result at the measurement point 401. The measurement point 401 (Invalid Sensor) not used for the focus operation is the measurement point 401 not used by the controller 107 to control the focus operation, and the controller 107 ignores the measurement result at the measurement point 401 in the control of the focus operation. Alternatively, with respect to the measurement point 401 not used for the focus operation, the measurement system 106 need not perform measurement, need not output the measurement result, or may output an invalid value. For example, the user can double-tap or click, by the pointing device, the measurement point (in FIG. 5, the position at which “O” or “-” is displayed) in the setting map 504b, thereby setting whether to use the measurement point. In another example, the setting map 504b can provide a user interface for prompting the user to set a weight for the measurement result at each of the plurality of measurement points 401. In this case, the controller 107 can set, for the measurement result at each of the plurality of measurement points 401, a weight corresponding to it in the focus operation, and execute the focus operation based on the weighted measurement results.

The display region 505 can display at least two of information representing the arrangement of the plurality of measurement points, information representing the height map in the exposure region, information representing the arrangement of the plurality of dies in the exposure region, and information representing the evaluation result of the repeatability of the measurement result at each of the plurality of measurement points. The display region 505 can be configured to superimpose and display at least two of these pieces of information.

The user interface 840 or the user interface screen 500 exemplified in FIG. 5 is effective for the user to make a setting concerning the use of each of the plurality of measurement points 401. For example, the user can make a setting concerning the use of each of the plurality of measurement points based on the pieces of information of the arrangement of the plurality of measurement points, the height map, the arrangement of the plurality of dies, the repeatability of the measurement result, and the like. For example, the user can set, as a measurement point not to be used, the measurement point located at the peak or valley in the height map based on the height map. Alternatively, the user can set the measurement point having low repeatability as a measurement point not to be used.

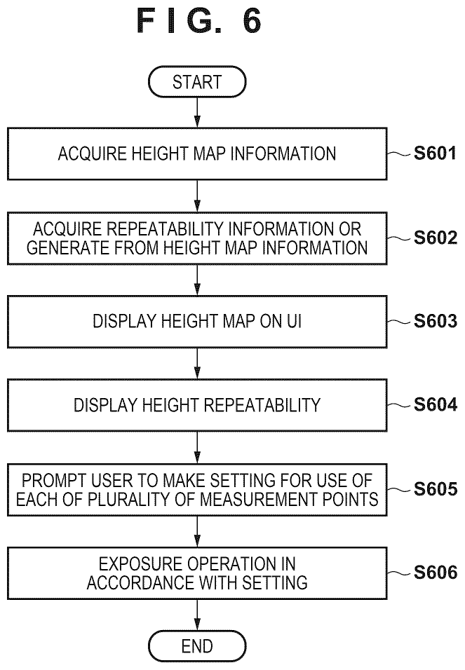

FIG. 6 exemplarily shows the operation of the exposure apparatus 100 associated with setting of the plurality of measurement points and the focus operation. This operation can be controlled by the controller 107, more specifically, the CPU (processor) 810 that operates in accordance with the program 822.

In step S601, the controller 107 acquires height map information representing the height distribution of the exposure region (shot region) of the substrate 108. In an example, the controller 107 can acquire the height map information in the exposure region (shot region) based on the output from the measurement system 106. The height map information is obtained by, for example, measuring, by the measurement system 106, the height distributions of the plurality of exposure regions (shot regions) of the substrate 108 loaded to the exposure apparatus 100 and held by the stage 105. In another example, the controller 107 can acquire, from the memory 820, height map information associated in advance with a lot including a plurality of substrates 108 to undergo the exposure operation in the exposure apparatus 100. Alternatively, the controller 107 may acquire, from another apparatus (for example, a management apparatus) connected to the network interface 830, height map information associated in advance with the lot including the plurality of substrates 108 to undergo the exposure operation in the exposure apparatus 100.

In step S602, the controller 107 can generate repeatability information representing the repeatability of the height measurement result based on the height map information acquired in step S601. For example, the controller 107 can generate repeatability information by calculating an index (index value) indicating variations among the plurality of sample shot regions based on the height map information. In another example, the controller 107 can acquire, from the memory 820, repeatability information associated in advance with the lot including the plurality of substrates 108 to undergo the exposure operation in the exposure apparatus 100. Alternatively, the controller 107 may acquire, from another apparatus (for example, a management apparatus) connected to the network interface 830, repeatability information associated in advance with the lot including the plurality of substrates 108 to undergo the exposure operation in the exposure apparatus 100.

In step S603, the controller 107 displays, on the user interface (UI) 840, the height map 503a corresponding to the height map information acquired in step S601. In step S604, the controller 107 displays, on the user interface (UI) 840, the repeatability map 504a obtained by mapping the repeatability information acquired or generated in step S602 to the plurality of measurement points.

In step S605, the controller 107 displays the setting map 504b on the user interface (UI) 840, and prompts the user to set whether to use each of the plurality of measurement points 401 in the focus operation.

In step S606, the controller 107 controls the focus operation of the exposure region with respect to the image plane of the projection optical system 104 by using the measurement result of the measurement system 106 based on the setting made in step S605, and exposes each exposure region of the substrate 108. Step S606 can be executed for, for example, the lot including the plurality of substrates.

The controller 107 may be formed as an information processing apparatus for controlling the focus operation in the exposure apparatus 100 including the measurement system capable of measuring the height of the substrate 108 at each of the plurality of measurement points 401 in the exposure region of the substrate 108. The controller 107 that is formed as such an information processing apparatus may or may not be connected to the exposure apparatus 100. The controller 107 or the CPU 810 (processor) can include the user interface 840 for prompting the user to make a setting concerning the use of each of the plurality of measurement points 401 in the exposure region. This setting can designate that the exposure apparatus 100 performs the focus operation by using the measurement result of the measurement system 106 based on the setting.

An article manufacturing method of manufacturing an article using the exposure apparatus 100 will be described below. The article manufacturing method can include an exposure step of exposing the substrate 108 using the exposure apparatus 100, a development step of developing the substrate 108 having undergone the exposure step, and a step of obtaining an article from the substrate 108 having undergone the development step. A photosensitive material (photoresist) is applied to the substrate 108 provided to the exposure apparatus 100. In the exposure step, the pattern of the original is transferred as a latent image pattern to the photosensitive material. In the development step, the latent image pattern is converted into a physical device pattern. The step of obtaining the article from the substrate 108 having undergone the development step can include, for example, a step of patterning the underlying layer using the device pattern. Furthermore, the step of obtaining the article from the substrate 108 having undergone the development step may include a step of dicing the substrate.

### OTHER EMBODIMENTS

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-027869, filed Feb. 27, 2024, which is hereby incorporated by reference herein in its entirety.

What is claimed is:

1. An exposure apparatus for exposing an exposure region of a substrate by projecting a pattern of an original to the exposure region by a projection optical system, comprising:
a measurement system configured to measure a height of the substrate at each of a plurality of measurement points in the exposure region;
a user interface configured to prompt a user to make a setting concerning use of each of the plurality of measurement points; and
a controller configured to control a focus operation of the exposure region with respect to an image plane of the projection optical system by using a measurement result of the measurement system based on the setting.

2. The apparatus according to claim 1, wherein the user interface prompts the user to set whether to use each of the plurality of measurement points.

3. The apparatus according to claim 1, wherein
the user interface prompts the user to set a weight for the measurement result at each of the plurality of measurement points, and
the controller controls the focus operation based on the weight set for the measurement result at each of the plurality of measurement points.

4. The apparatus according to claim 1, wherein the user interface displays information representing an arrangement of the plurality of measurement points.

5. The apparatus according to claim 4, wherein the user interface further displays information representing a height map in the exposure region.

6. The apparatus according to claim 4, wherein the user interface further displays information representing an arrangement of a plurality of dies in the exposure region.

7. The apparatus according to claim 4, wherein the user interface further displays information representing an evaluation result of repeatability of the measurement result at each of the plurality of measurement points.

8. The apparatus according to claim 7, wherein the repeatability indicates repeatability among a plurality of exposure regions of the substrate.

9. The apparatus according to claim 7, wherein the repeatability is an index indicating variations among a plurality of exposure regions of the substrate.

10. The apparatus according to claim 1, wherein the user interface displays at least two of
information representing an arrangement of the plurality of measurement points,
information representing a height map in the exposure region,
information representing an arrangement of a plurality of dies in the exposure region, and
information representing an evaluation result of repeatability of the measurement result at each of the plurality of measurement points.

11. The apparatus according to claim 1, wherein the user interface superimposes and displays at least two of
information representing an arrangement of the plurality of measurement points,
information representing a height map in the exposure region,
information representing an arrangement of a plurality of dies in the exposure region, and
information representing an evaluation result of repeatability of the measurement result at each of the plurality of measurement points.

12. An information processing apparatus for controlling a focus operation in an exposure apparatus including a measurement system capable of measuring a height of a substrate at each of a plurality of measurement points in an exposure region of the substrate, comprising:
a user interface configured to prompt a user to make a setting concerning use of each of the plurality of measurement points in the exposure region,
wherein the setting designates that the exposure apparatus performs the focus operation by using a measurement result of the measurement system based on the setting.

13. A control method for an exposure apparatus including a measurement system capable of measuring a height of a substrate at each of a plurality of measurement points in an exposure region of the substrate, comprising:
prompting a user to make a setting concerning use of each of the plurality of measurement points in the exposure region; and
exposing the exposure region by controlling a focus operation of the exposure region with respect to an image plane of a projection optical system of the exposure apparatus by using a measurement result of the measurement system based on the setting.

14. A non-transitory computer readable medium storing program for causing a computer to execute a control method for an exposure apparatus defined in claim 13.

15. An information processing method of controlling a focus operation in an exposure apparatus including a measurement system capable of measuring a height of a substrate at each of a plurality of measurement points in an exposure region of the substrate, comprising:
prompting a user to make a setting concerning use of each of the plurality of measurement points in the exposure region,
wherein the setting designates that the exposure apparatus performs the focus operation by using a measurement result of the measurement system based on the setting.

16. A non-transitory computer readable medium storing program for causing a computer to execute an information processing method defined in claim 15.

17. An article manufacturing method comprising:
exposing a substrate using an exposure apparatus defined in claim 1;
developing the substrate having undergone the exposing; and
obtaining an article by processing the substrate having undergone the developing.

18. An article manufacturing method comprising:
exposing a substrate by controlling an exposure apparatus in accordance with a control method for the exposure apparatus defined in claim 13;
developing the substrate having undergone the exposing; and
obtaining an article by processing the substrate having undergone the developing.
